(19) United States
(12) Patent Application Publication
(10) Pub. No.: US 2008/0124924 A1
(43) Pub. Date: May 29, 2008

(54) Scheme for copper filling in vias and trenches

(75) Inventor: Mehul Naik, San Jose, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: Applied Materials, Inc.

(21) Appl. No.: 11/488,514

(22) Filed: Jul. 18, 2006

(51) Int. Cl. H01L 21/768

(52) U.S. Cl. 438/675; 438/680; 438/687; 257/E21.586

(57) ABSTRACT

Embodiments of the present invention generally relate to methods and apparatuses using supercritical fluids and/or dense fluids to deposit a metal material on the surface of a substrate. In one embodiment, a metal material layer is deposited by applying a supercritical fluid, a dense fluid, or combinations thereof and a metal-containing precursor to the surface of a substrate inside a substrate processing chamber. In another embodiment, a first metal material and a second metal material is sequentially deposited and annealing is performed to form a metal alloy material on the surface of a substrate. In still another embodiment, a copper material layer is deposited by applying a supercritical fluid, a dense fluid, or combinations thereof and a copper containing precursor to the surface of the substrate.

### BACKGROUND OF THE INVENTION

1. Field of the Invention

Embodiments of the present invention generally relate to methods and apparatuses using supercritical fluids and/or dense fluids in semiconductor applications. More particularly, embodiments of the present invention relate to methods and apparatuses using supercritical fluids and/or dense fluids for material deposition.

2. Description of the Related Art

Copper and its alloys have become the metals of choice for sub-micron interconnect technology because copper has a lower resistivity than aluminum, (1.7 μΩ-cm compared to 3.1 μΩ-cm for aluminum), and a higher current carrying capacity and significantly higher electromigration resistance. These characteristics are important for supporting the higher current densities experienced at high levels of integration and increased device speed. Further, copper has a good thermal conductivity and is available in a highly pure state. One problem with the use of copper is that copper diffuses into silicon, silicon dioxide, and other dielectric materials which may compromise the integrity of devices. Tantalum nitride, for example, has been used as a barrier material to prevent the diffusion of copper into underlying layers. However, tantalum nitride and other barrier material layers are poor wetting agents, which may cause numerous problems, for a copper material layer to deposit thereon.

Vapor deposition processes, such as physical vapor deposition (PVD) and chemical vapor deposition (CVD), have played an important role in copper metallization to deposit materials on substrates. Copper materials deposited by PVD generally provide good adhesion to barrier materials and a typical fabrication process includes depositing a barrier layer over a feature, physical vapor depositing a copper seed layer over the barrier layer, and then electroplating a copper conductive material layer over the copper seed layer to fill the feature. Finally, the deposited layers and the dielectric layers are planarized, such as by chemical mechanical polishing (CMP), to define a conductive interconnect feature.

However, inherent PVD limitations, such as poor conformality, are potential road-blocks for filing copper materials into interconnect features. The non-conformal problem can be especially severe in overhangs at the trench or via openings of a copper interconnect. As the geometries of electronic devices continue to shrink and the density of devices continues to increase, the size and aspect ratio of the features are becoming more aggressive, e.g., feature sizes of 0.07 μm and aspect ratios of 10 or greater. Accordingly, conformal deposition of materials to form these devices is becoming increasingly important.

Alternatively, CVD provides conformal material deposition for devices with high aspect ratios and shrinking geometries. However, a CVD-deposited copper seed layer may agglomerate and become discontinuous, and in turn, prevent uniform deposition of a subsequent copper conductive material layer over the copper seed layer. In addition, the conformality of a CVD-deposited copper seed layer may be a disadvantage for complete fill of trenches and other features, when the densities of the features vary over the surface of the substrate. As a result, forbidden gaps, where small features and trenches in dense area are filled but large feature and trenches in less dense area are not completely filled, may be formed and such incomplete fillings of features tend to become worse after subsequent processing by CMP and high temperature thermal stressing, resulting in de-wetting, formation of voids in the copper layer, and electrical failure.

Another problem with copper materials deposited by CVD at a relatively low deposition temperature and high deposition rate is that sufficient vapor pressure are required for reaction precursors to chemically decompose and react on the surface of the substrate. Thus, highly volatile copper precursors, such as fluorinated copper precursors, are used. As a result, the CVD deposited copper material often contains contamination materials at the barrier and copper interface, leading to poor adhesion issues.

Therefore, there is a need for an apparatus and a method of forming an improved interconnect structure and depositing a metal material on a substrate.

### SUMMARY OF THE INVENTION

Embodiments of the present invention generally relate to methods and apparatuses using supercritical fluids and/or dense fluids in semiconductor applications. In one embodiment, a metal material layer is deposited by applying a supercritical fluid, a dense fluid, or combinations thereof and a metal-containing precursor to the surface of a substrate inside a substrate processing chamber. In another embodiment, a copper material layer is deposited by applying a supercritical fluid, a dense fluid, or combinations thereof and a copper containing precursor to the surface of the substrate.

One method of processing a substrate inside a chamber includes delivering a fluid selected from the group consisting of a supercritical fluid, a dense fluid, and combinations thereof to the surface of the substrate having at least one feature thereon, delivering one or more metal-containing precursor compounds to the surface of the substrate inside the chamber, and depositing a metal material on the surface of the substrate. In addition, a mixture of the fluid and the one or more metal-containing precursor compounds is formed prior to being delivered inside the chamber. Alternatively, a mixture of the fluid and the one or more metal-containing precursor compounds is formed after being delivered inside the chamber.

Another method of processing a substrate inside a chamber includes delivering a fluid selected from the group consisting of a supercritical fluid, a dense fluid, and combinations thereof to the surface of the substrate having at least one feature thereon, sequentially delivering at least two different metal-containing precursor compounds to the chamber, and depositing a first metal material and a second metal material on the surface of the substrate.

In one embodiment, a copper see layer is formed over a barrier material layer on the surface of a substrate having features thereon. In another embodiment, a first metal material and a second metal material are sequentially deposited and annealing is performed to form a metal alloy material on the surface of a substrate.

In still another embodiment, a substrate structure is cleaned and/or dried by applying a supercritical fluid, a dense fluid, or combinations thereof before and/or after the metal material is deposited. Advantageously, substrate processing including deposition, cleaning, among others, can be performed using the same substrate processing chamber.

The invention further provides an apparatus for processing a substrate, including a chamber comprising walls defining an enclosure, the chamber adapted to be pressurized to a pressure of at least about 1000 psi, a substrate support disposed within the enclosure, the substrate support having a substrate receiving surface, a fluid delivery device adapted to deliver a fluid selected from the group consisting of a supercritical fluid, a dense fluid, and combinations thereof to the substrate receiving surface, a fluid supply adapted to deliver one or more metal-containing precursor compounds, a fluid line coupled between the fluid delivery device and the fluid supply, and one or more heating elements.

In addition, the invention provides a system including one or more first chambers adapted to deliver one or more metal-containing precursor compounds and a fluid selected from the group consisting of a supercritical fluid, a dense fluid, and combinations thereof to the substrate receiving surface and deposit a metal material on the surface of a substrate using a supercritical fluid and/or a dense fluid process, one or more second chambers selected from the group consisting of a wet clean chamber; a dry stripping chamber, a dry etch chamber, and a porous low-k deposition chamber; and combinations thereof, and one or more transfer robots adapted to transfer substrates between the first chambers and second chambers.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of one embodiment of a processing chamber adapted to deliver a supercritical fluid and/or a dense fluid to a substrate.

FIG. 2 is a schematic cross-sectional view of one embodiment of a processing chamber adapted to deliver a supercritical fluid and/or a dense fluid.

FIG. 3 is a flow chart of one embodiment of an application of depositing a metal material with a supercritical fluid and/or dense fluid.

FIGS. 4A-4D are schematic cross-sectional views of one example of a substrate structure at various stages of substrate processing.

FIG. 5 is a schematic top view of one embodiment of an integrated substrate processing system.

FIG. 6 is a schematic top view of another embodiment of an integrated substrate processing system.

### DETAILED DESCRIPTION OF THE INVENTION

Embodiments of the present invention generally relate to methods and apparatuses of employing supercritical fluids and/or dense fluids to deposit a metal material on the surface of a substrate from one or more precursor compounds, such as a metal-containing precursor. In one embodiment, copper materials and other metal materials are deposited as a thin layer with good adhesion to underlying materials on the surface of the substrate to conformally fill features thereon. For example, a copper seed layer is deposited over the surface of a substrate having a barrier material layer thereon using one or more copper-containing precursors and a supercritical fluids and/or dense fluids inside a process chamber.

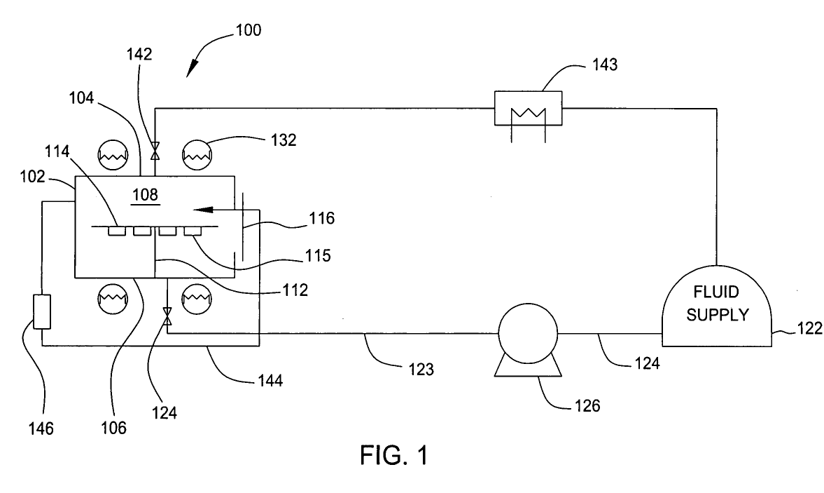

FIG. 1 is a schematic cross-sectional view of one embodiment of a processing chamber 100, adapted to deliver a supercritical fluid and/or a dense fluid, and one or more precursors, such as a metal-containing precursor to deposit a material on the surface of a substrate, in which the fluids are heated inside the chamber. The processing chamber 100 includes sidewalls 102, a top wall 104, and a bottom wall 106 which define an enclosure 108. The processing chamber 100 may include a slit valve 116 to provide access for a robot to transfer and receive substrates from the enclosure 108. A substrate support 112 having a platter 114 thereon is adapted to support a substrate within the enclosure 108. The platter 114 defines a substrate receiving surface for receiving a substrate. In one embodiment, the platter 114 may be adapted to rotate the substrate during processing.

In one embodiment, the volume of the enclosure 108 includes a small volume to reduce the amount of fluid necessary to fill the enclosure 108. For example, the processing chamber 100 may be adapted to process 300 mm diameter substrates and has a volume of about 10 liters or less, more preferably about 5 liters or less. However, the invention is not limited any specific substrate sizes or substrate types.

The processing chamber 100 may optionally further include one or more acoustic or sonic transducers 115. As shown, the transducers 115 are located on the substrate support 112 but may be located in other areas of the enclosure 108. The transducers 115 create acoustic or sonic waves directed towards the surface of a substrate to help agitate the fluid. In other embodiments, the transducers may comprise a rod, plunger, or plate located within the enclosure. Other aspects and embodiments of a substrate support adapted to provide sonic agitation are disclosed in co-pending U.S. patent application Ser. No. 09/891,849, filed Jun. 25, 2001 (Publication No. 2002/0029788A1) and in U.S. patent application Ser. No. 09/891,791, filed Jun. 25, 2001 (Publication No. 2002/0063169A1, now abandoned), both of which are herein incorporated by reference in their entirety to the extent not inconsistent with the present disclosure.

One or more fluid lines 123 couple one or more fluid supplies 122 and one or more fluid inlets 124 to the processing chamber 100 (only one fluid line is representatively illustrated in FIG. 1). The one or more fluid lines 123 and the one or more fluid supplies 122 are used to provide a supercritical fluid, a dense fluid, a carbon dioxide fluid, a metal-containing precursor, and other fluids, precursors into the processing chamber 100. A pump 126 may be disposed on the fluid lines 123 between the fluid inlets 124 and the fluid supplies 122 for delivering any fluids and precursors, when needed, from the fluid supplies 122 into the enclosure 108 of the processing chamber 100.

One or more heating elements 132 are disposed proximate or inside the walls 102, 104, 106 of the processing chamber 100 to maintain the temperature inside the processing chamber 100 to a desired temperature of from room temperature to about 250° C. or higher, suitable for substrate processing, such as substrate cleaning, deposition, post-processing treatment, among others. The heating elements 132 may comprise resistive heating elements, fluid channels for a heat control fluid, and/or other heating devices. The heating elements 132 heat the fluid inside the enclosure 108 to a desired temperature of the heated fluid. The processing chamber 100 may optionally include cooling elements for rapid cooling of the substrate or the processing chamber.

The processing chamber 100 may optionally include a loop 144 for re-circulating fluids and precursors to and from the processing chamber 100. The loop 144 may further include a filter 146, such as an activated charcoal filter, to help purify the fluids. In one aspect, the loop 144 helps produce a laminar flow of the fluids within the enclosure 108 and helps prevent a stagnant fluid bath. It is believed that a laminar flow helps to sweep particles away from the substrate and to prevent particles from re-depositing on the substrate.

One or more fluid outlets 142 are coupled to the processing chamber 100 for removal of the fluids from the enclosure 108. The fluid outlets 142 may release the fluids to atmosphere, may direct the used fluids to storage, or may recycle the fluids for re-use. As shown, the fluid outlet 142 is coupled to the fluid supply 122 to recycle the fluid for re-use. A condenser 143 may be coupled between the fluid outlets 142 and the fluid supplies 122 to condense the fluids prior to being directed to the fluid supplies 122.

As shown, the fluid inlet 124 is disposed at a bottom wall 106 of the processing chamber 100 while the fluid outlet 142 is disposed at the top wall 104 of the processing chamber 100. However, the fluid inlet 124 and the fluid outlet 142 may be disposed at other areas of the walls 102, 104, 106 of the processing chamber 100. In addition, the fluid inlet 124 may be optionally coupled to nozzles, showerhead, or other fluid delivery device to direct the fluid towards the substrate placed inside the processing chamber 100.

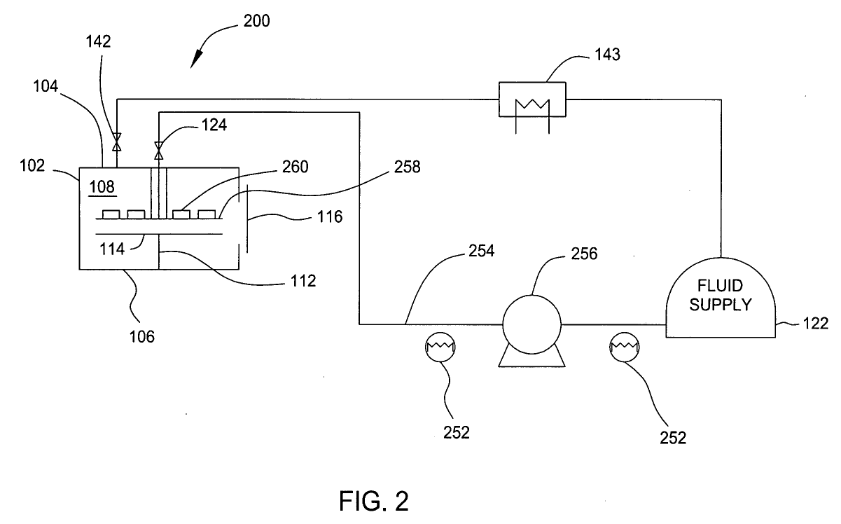

FIG. 2 is a schematic cross-sectional view of one embodiment of a processing chamber 200 adapted to deliver a supercritical fluid and/or a dense fluid, and one or more precursors, such as a metal-containing precursor, to deposit a material on the surface of a substrate, in which the fluids are heated in-line. Some of the parts of the processing chamber 200 of FIG. 2 are similar to the parts of the processing chamber 100 of FIG. 1. As a consequence, consistent reference numerals have been used for clarity of description where appropriate.

The processing chamber 200 includes one or more heating elements 252 to heat a fluid line 254 coupling the one or more fluid supplies 122 and the processing chamber 200. A pump/compressor 256 may be disposed on the fluid line 254 to deliver the fluids to the enclosure 108. The one or more heating elements 252 may be disposed before and/or after the pump/compressor 256. The fluid line 254 is coupled to a fluid delivery device 258, such as a showerhead, nozzle, or plate, disposed above the substrate support 112.

The fluid delivery device 258 may include optional transducers 260 adapted to create acoustic or sonic waves directed towards the surface of a substrate to help agitate the fluid. In addition, the transducers may be disposed at other locations within the enclosure 108. In one embodiment, the substrate support 112 may be adapted to rotate the substrate and/or the fluid delivery device may be adapted to rotate to help agitate the fluid. The processing chamber 200 may also optionally include additional heating and/or cooling elements proximate or inside the chamber walls.

In one embodiment, one or more precursors and one or more fluids are delivered as a mixture and brought into a supercritical or dense fluid state using the fluid delivery device 258, where the mixture contains one or more metal-containing precursor and other precursors dissolved and carried by a supercritical fluid and/or a dense fluid. In another embodiment, one or more precursors and one or more fluids are delivered into the processing chambers 100, 200 into a mixture prior to bringing the mixture into a supercritical or dense fluid state by setting required conditions inside the processing chambers 100, 200. In still another embodiment, the mixture exists as a supercritical fluid and/or dense fluid state at a partial volume of the enclosure 108 proximate the surface of the substrate inside the processing chambers 100, 200. In a further embodiment, a supercritical fluid and/or dense fluid is supplied into the processing chamber until the whole enclosure 108 is at a supercritical fluid and/or dense fluid state.

One or more system controllers are connected to the processing chambers 100, 200 to be adapted to control the functions of various components such as the one or more fluid delivery devices, heating elements, power supplies, substrate supports, lift motors, flow controllers for precursor injection, vacuum pump, robots, and other associated chamber and/or processing functions. The system controllers execute system control software stored in a memory, which in s preferred embodiment is a hard disk drive, and can include analog and digital input/output boards, interface boards, and stepper motor controller boards. Optical and/or magnetic sensors are generally used to move and determine the position of movable mechanical assemblies. One examples of such a processing chamber is described in U.S. application Ser. No. 11/038,456, entitled “Using Supercritical and Dense Fluid in Semiconductor Applications,” by Verhaverbeke, which is assigned to Applied Materials, Inc, the assignee of the present invention. The aforementioned patent application is hereby incorporated by reference to the extent not inconsistent with the disclosure herein. The above processing chamber description is mainly for illustrative purposes, and other processing chambers may also be employed for practicing embodiments of the invention.

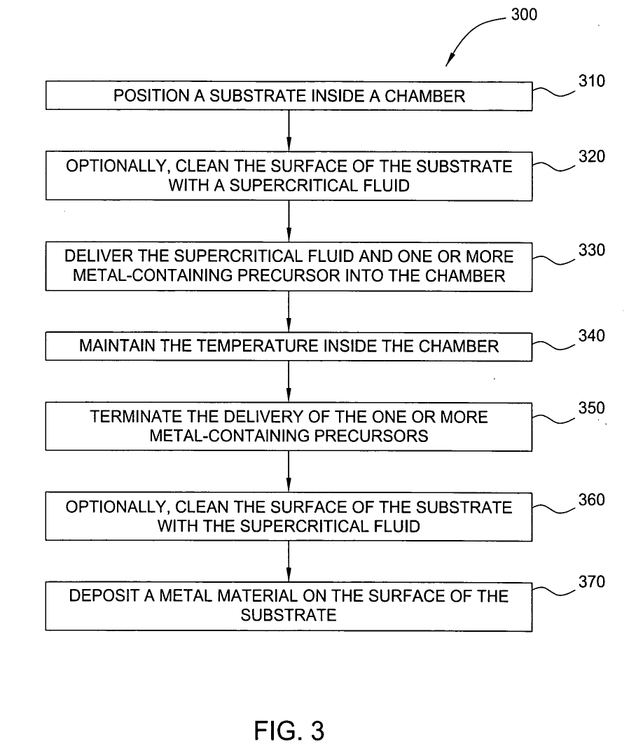

FIG. 3 is a process flow diagram illustrating a method 300 according to one or more embodiments of the invention. At step 310, a substrate for depositing a metal material thereon is positioned on a substrate support inside a chamber. At step 320, the surface of the substrate may optionally be cleaned with a supercritical fluid, which can be delivered into the chamber in its supercritical state or, alternatively, formed into its supercritical state inside the chamber. The substrate can be cleaned inside the chamber for a desired processing time, such as about 1 second or larger. Preferably, the cleaning time is between about 5 seconds to about 30 seconds, such as about 10 seconds.

The term “supercritical fluid” as used herein refers to a substance above its critical point. The term “dense fluid” as used herein refers to a substance at or below its critical point. Dense fluid preferably includes a substance at or near its critical point. In certain embodiments, a dense fluid includes a substance that is at a state in which its density is at least ⅕, preferably at least ⅓, more preferably at least ½, of the density of the substance at its critical point. Examples of substances, fluids, and/or gases which may be used to advantage as supercritical fluids and/or dense fluids include, but are not limited to, carbon dioxide, xenon, argon, helium, krypton, nitrogen, methane, ethane, propane, pentane, ethylene, methanol, ethanol, isopropanol, isobutanol, cyclohexanol, ammonia, nitrous oxide, oxygen, silicon hexafluoride, methyl fluoride, chlorotrifluoromethane, water, and combinations thereof.

For example, supercritical carbon dioxide can be used because of its unique properties as a supercritical fluid and the reduced environmental risks in the use of carbon dioxide. For substances which exhibit supercritical fluid properties, when the substance is above its critical point (critical temperature and critical pressure), the phase boundary between the gas phase and liquid phase disappears, and the substance exists in a single supercritical fluid phase. In the supercritical fluid phase, a substance assumes some of the properties of a gas and some of the properties of a liquid. For example, supercritical fluids have diffusivity properties similar to gases but solvating properties similar to liquids. Therefore, supercritical fluids have good dissolving/cleaning properties and can be used herein to clean the surface of the substrate and/or dissolving one or more precursor compounds.

At step 330, the substance for forming a supercritical fluid and one or more precursor compounds for depositing a metal material on the surface of the substrate are formed into a mixture and delivered into the chamber. According to one or more embodiments of the invention, the mixture can be formed prior to or after the substance is formed into its supercritical state. For example, a carbon dioxide supercritical fluid may be formed and combined with one or more precursor compounds, where the carbon dioxide supercritical fluid, e.g., serving as a solvent, dissolve the one or more precursors into a solution mixture, which can in turn be delivered into the chamber. Alternatively, carbon dioxide and one or more precursors may be mixed together and formed into a supercritical fluid mixture prior to being delivered into the chamber or directly inside the chamber.

Note wishing to be bound by theory, it is contemplated that a supercritical fluid provides good solubility for the one or more precursor compounds, especially for organometallic precursor compounds, such that a broad range of precursor compounds can be solubilized. The solubilized precursor compounds can then be easily adsorbed to the surface of the substrate for depositing a material, such as a metal material, thereon at a desired deposition temperature. Thus, it may not necessary to use highly volatile and toxic precursor compounds which often lead to contamination and toxic waste issues.

Exemplary precursor compounds for depositing a metal material, such as copper, may include, but are not limited to, copper (II) bis-hexafluoroacetylacetonate [Cu(hfac)2], 1,5-cyclo-octadiene-copper (I)-hexafluoroacetylacetonate [COD-Cu-hfac], Bis(2,2,7-trimethyloctane-3,5-dionato) copper (II) [Cu(tmod)₂], Bis(2,2,6,6-tetramethyl-3,5-heptanedione) copper (II) [Cu(tmhd)2], Cu(acac)2, Cuhfac(TMVS), Cu(DPM)2, their derivatives, and combinations thereof.

Additional exemplary precursor compounds for depositing a metal material, such as nickel (Ni), aluminum (Al), platinum (Pt), palladium (Pd), ruthenium (Ru), manganese (Mn), and magnesium (Mg) may include, but are not limited to, bis(cyclopentadienyl) Ni, Ni(acac)2, Trimethylamine Alane(TEAA), Dimethylaluminum hydride(DMAH), Tri-isobutylAluminum(TIBA), pt(acac)2, Pd(acac)2, pd(C3H5)hfac, Bis(pentamethylcyclopentadienyl) manganese(II), Bis(cyclopentadienyl) manganese(II), Bis(ethylcyclopentadienyl) manganese(II), Bis(tetramethylcyclopentadienyl) manganese(II), Magnesium bis(2,2,6,6-tetramethyl-3,5-heptanedionate) hydrate, Bis(ethylcyclopentadienyl) magnesium, Bis(cyclopentadienyl) magnesium(II), Bis(pentamethylcyclopentadienyl) magnesium, ruthenium beta diketonates, cyclopentadienyl ruthenium, their derivatives, and combinations thereof.

In one or more embodiments, the one or more metal-containing precursor compounds delivered by the supercritical fluid may include at least two different metal-containing precursor compounds delivered sequentially to deposit a first metal material and a second metal material. For example, aluminum may be deposited by delivering an aluminum-containing organometallic precursor compound into the chamber before a copper-containing organometallic precursor compound is delivered into the chamber, such as that a metal alloy containing aluminum and copper can be formed, e.g., by annealing the substrate having the two metal materials deposited thereon.

In another embodiment, two different metal-containing precursor compounds can be delivered sequentially to deposit a first metal material and a second metal material which may not form alloy. For example, a ruthenium layer can be deposited before a copper layer is deposited, each as a separate layer, without forming into a metal alloy layer.

At step 340, the temperature inside the chamber is maintained, such as to a temperature that provides the best solubility for the one or more metal-containing precursor compounds, e.g., from room temperature to about 100° C. or higher, or from about 50° C. to about 400° C. or higher. In addition, the pressure inside the chamber is also maintained, such as to a pressure around or above the supercritical pressure for forming a supercritical fluid of the one ore more precursor compounds. The flows of the one ore more precursor compounds are maintained for a deposition time, such as about 5 second or longer, or about 60 seconds or longer.

Additionally, a carrier gas, additional reactive gases, and/or an inert gas can be delivered into the chamber. For example, additional reducing agents, such as hydrogen (H2) gas, alcohol type compounds, can be added to react with the metal-containing precursor and reduce the metal state, e.g., reducing Cu²⁺ into Cu⁰, Carrier inert gases, such as argon (Ar), helium (He), nitrogen (N₂), etc., can also be added inside the chamber.

At step 350, the flows of the one ore more precursor compounds are terminated. For example, the flow of one or more copper-containing precursor is terminated. Optionally, at step 360, the surface of the substrate can be cleaned with the supercritical fluid by continuing delivering the one or more fluid after the flows of the one ore more precursor compounds are terminated. The time period for maintaining the flow of the cleaning fluids, such as a supercritical fluid, is about 1 second or larger. Preferably, the time period for the supercritical cleaning fluid is between about 1 second to about 1 minute, such as between about 5 seconds to about 180 seconds, e.g., a time period of about 5 seconds to about 10 seconds. For example, the flow of the supercritical cleaning fluid is continued and re-circulated into the loop 144 to help removing contaminants, such as residual organic particles, non-reactive metal particles, non-reactive precursor compounds, away from the substrate surface. The contaminants can be further pumped out of the chamber before the remaining supercritical cleaning fluid flow is terminated.

At step 370, a conformal material layer, such as a conformal metal material layer is deposited on the substrate inside the chamber, and the supercritical fluid is terminated. The deposition of the metal material takes place without the need to vaporize the precursor compounds since the precursor compounds can be solubilized in the supercritical fluid.

One example of a method of processing a substrate with a carbon dioxide fluid in the processing chamber 100 includes transferring a substrate through the slit valve 116 to the substrate support 112 and closing the slit valve 116. A mixture of carbon dioxide and a copper-containing precursor is pumped by pump 126 into the processing chamber 100 from the fluid supply 122 to a desired pressure for supercritical carbon dioxide within the enclosure 108. The fluid inlet 124 is closed and the heating elements 132 heat the carbon dioxide to a desired temperature so that the carbon dioxide is at a supercritical fluid state and/or a dense fluid state. The mixture is optionally agitated through application of the transducers 115 and/or rotation of the substrate. The carbon dioxide supercritical fluid is optionally re-circulated within the enclosure 108 through the loop 144. After the substrate has been processed with the mixture for a desired time period, the fluid outlet 142 is opened and the carbon dioxide is vented or released to atmosphere, directed to the condenser 143, or directed to storage. In one embodiment, releasing the pressure of the chamber causes the carbon dioxide at a supercritical fluid state and/or a dense fluid state to be at a gas state which can be easily removed from the processing chamber 100. The substrate may be optionally heated during venting to prevent cooling of the substrate and to prevent moisture uptake. Other methods of processing a substrate with a supercritical fluid and/or dense fluid are also possible in processing chamber 100.

Another example of a method of processing a substrate with a carbon dioxide fluid in the processing chamber 200 comprises transferring a substrate to the substrate support 112. Carbon dioxide is transferred by pump/compressor 256 from the fluid supply 122 through the fluid line 254 at a desired pressure. The heating elements 252 heat the carbon dioxide to a desired temperature as the fluid is being transferred though the fluid line 254. The fluid delivery device 258 delivers a supercritical carbon dioxide fluid and/or a dense carbon dioxide fluid to the substrate. The carbon dioxide is optionally agitated through application of the transducers 260, rotation of the substrate, and/or rotation of the fluid delivery device. The enclosure 108 may be pressurized or unpressurized during application of the supercritical carbon dioxide fluid and/or dense carbon dioxide fluid by the fluid delivery device 258. In addition, a one or more copper-containing precursors are delivered into the chamber and through the same fluid line or a different fluid line and formed into a mixture with the supercritical carbon dioxide in the fluid line or inside the chamber. After application of the carbon dioxide supercritical fluid and/or the mixture to the substrate, the carbon dioxide is vented or released to atmosphere, directed to the condenser 143, or directed to storage. The substrate may be optionally heated during venting to prevent cooling of the substrate and to prevent moisture uptake. Other methods of processing a substrate with a supercritical fluid and/or dense fluid are also possible in the processing chamber 200.

According to one or more embodiment of the invention, a metal alloy containing a first metal and a second metal can be deposited on the surface of the substrate using at least two different metal-containing precursor compounds. For example, copper alloy can be deposited by co-deposition, where a first metal film is deposited. Exemplary first metal film includes nickel (Ni), aluminum (Al), platinum (Pt), palladium (Pd), etc. before a second metal film, such as copper (Cu) is deposited. Then, annealing can be performed to form a mixed alloy. The deposited copper alloy and other metal alloys can then re-distributed through the entire feature during the higher thermal budget processes, such as post ECP or post CMP.

A supercritical fluid can be used to deposit metal material on the surface of a substrate. Because the supercritical fluid has low surface tension, diffusivity of a gas, density of a liquid, a metal film that is conformal, mechanically stronger, adhere well to underlying materials is formed even with the same precursors in comparison to deposition by physical vapor deposition, spin-on, or chemical vapor deposition. It is believed that using a supercritical fluid as a solvent during deposition causes the deposited film to have a lower amount of dangling bond and imperfect cells in comparison to deposition by spin-on or by chemical vapor deposition.

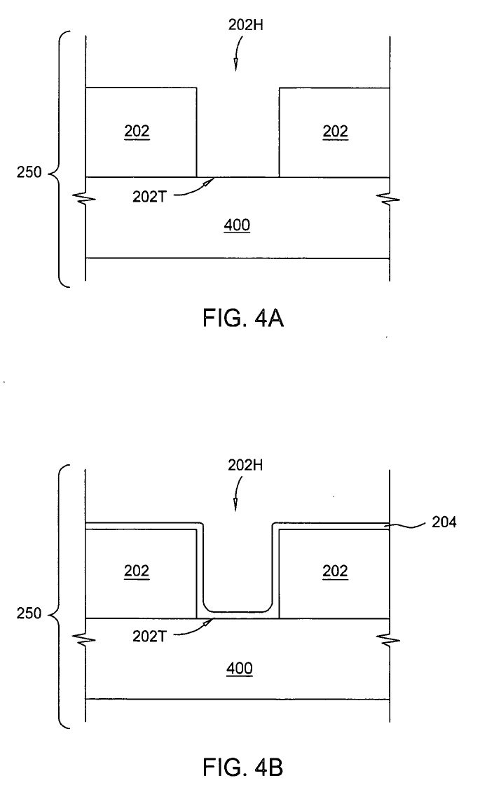

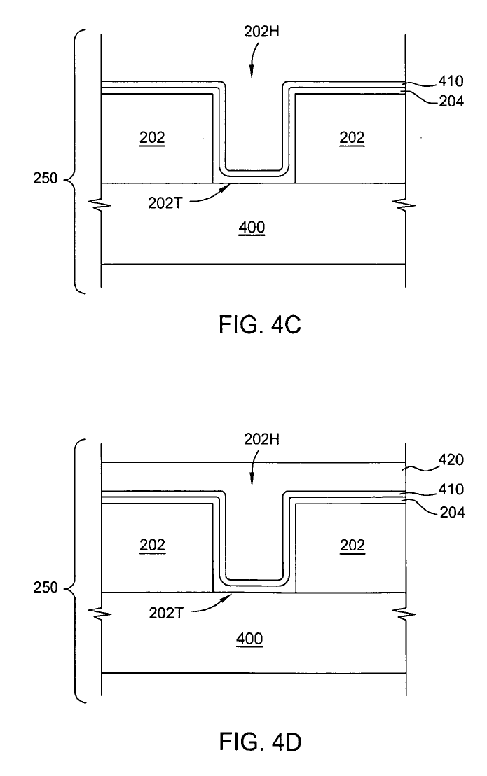

FIGS. 4A-4D are schematic cross-sectional views of one example of a substrate 400 at various stages of semiconductor processing. Supercritical fluids and/or dense fluids, such as a carbon dioxide fluid, are useful in processing of the substrate 400 at one or more stages of FIGS. 4A-4D, as described further below.

FIG. 4A is a schematic cross-sectional view of one embodiment of a substrate 400 having a dielectric layer 202 deposited thereon. Depending on the processing stage, the substrate 400 may be a silicon semiconductor wafer, or other material layer, which has been formed on the wafer. The dielectric layer 202 may be an oxide, a silicon oxide, carbon-silicon-oxide, a fluoro-silicon, a porous dielectric, or other suitable dielectric formed and patterned to provide a contact hole or via 202H extending to an exposed surface portion 202T of the substrate 400. For purposes of clarity, the substrate 400 refers to any workpiece upon which film processing is performed, and a substrate structure 250 is used to denote the substrate 400 as well as other material layers formed on the substrate 400, such as the dielectric layer 202. It is also understood by those with skill in the art that the present invention may be used in a dual damascene process flow.

FIG. 4B is a schematic cross-sectional view of one embodiment of a barrier layer 204 formed over the substrate structure 250 of FIG. 4A, for example, by atomic layer deposition (ALD), chemical vapor deposition (CVD), or physical vapor deposition (PVD). Preferably, the barrier layer comprises a tantalum nitride layer. Examples of other barrier layer materials which may be used include titanium (Ti), titanium nitride (TiN), titanium silicon nitride (TiSiN), tantalum (Ta), tantalum silicon nitride (TaSiN), ruthenium (Ru), tungsten (W), tungsten nitride (WN), tungsten silicon nitride (WSiN), and combinations thereof.

FIG. 4C includes depositing a copper seed layer 410 over a barrier layer 204 of FIG. 4B using methods and apparatus of the invention. The copper seed layer 410 formed thereon is very conformal and provides good adhesion to the underlying barrier layer 204. The copper seed layer 410 deposited by the methods and apparatus of the invention may comprise a pure copper material or a copper metal alloy that aids in subsequent deposition of materials thereover. A copper alloy seed layer may comprise copper and a second metal, such as aluminum, magnesium, titanium, zirconium, tin, other metals, and combinations thereof. The second metal preferably comprises aluminum, magnesium, titanium, and combinations thereof and more preferably comprises aluminum. In certain embodiments, the copper alloy seed layer comprises a second metal in a concentration having the lower limits of about 0.001 atomic percent, about 0.01 atomic percent, or about 0.1 atomic percent and having the upper limits of about 5.0 atomic percent, about 2.0 atomic percent, or about 1.0 atomic percent. The concentration of the second metal in a range from any lower limit to any upper limit is within the scope of the present invention. The concentration of the second metal in the copper alloy seed layer is preferably less than about 5.0 atomic percent to lower the resistance of the copper alloy seed layer. The term “layer” as used in the specification is defined as one or more layers. For example, for a copper alloy seed layer comprising copper and a second metal in a concentration in a range between about 0.001 atomic percent and about 5.0 atomic percent, the copper alloy seed layer may comprise a plurality of layers in which the total composition of the layers comprises copper and the second metal in a concentration between about 0.001 atomic percent and about 5.0 atomic percent. For illustration, examples of a copper alloy seed layer comprising a plurality of layers in which the total composition of the layers comprises copper and the second metal in a concentration between about 0.001 atomic percent and about 5.0 atomic percent may comprises a first seed layer comprising the second metal and a second seed layer comprising copper, may comprise a first seed layer comprising a copper/second metal alloy and a second seed layer comprising a copper/second metal alloy, or may comprise a first seed layer comprising a copper/second metal alloy and a second seed layer comprising copper, etc.

The copper material layer or copper metal alloy seed layer may be deposited to a thickness of at least about a 5 Å coverage of the sidewalls of the feature or to a thickness of at least a continuous coverage of the sidewalls of the feature. In one embodiment, the copper alloy seed layer is deposited to a thickness at the field areas between about 10 Å and about 2000 Å.

FIG. 4D further illustrates depositing a copper conductive material layer 420 over the copper seed layer 410 to fill the feature. The term “copper conductive material layer” as used in the specification is defined as a layer comprising copper or a copper alloy. The copper conductive material layer 420 may be deposited by electroplating, physical vapor deposition, chemical vapor deposition, electroless deposition or a combination of techniques. Preferably, the copper conductive material layer 420 is deposited by electroplating because of the bottom-up growth which may be obtained in electroplating processes. An exemplary electroplating method is described in U.S. Pat. No. 6,113,771, entitled “Electro Deposition Chemistry”, issued Sep. 5, 2000, and is incorporated herein by reference to the extent not inconsistent with this invention.

One embodiment of the invention includes cleaning and/or drying a substrate structure by applying a supercritical fluid and/or a dense fluid thereto. In one embodiment, a carbon dioxide fluid is used at a pressure between about 1,000 psi and about 5,000 psi and a temperature of at least about 31° C. In another embodiment, the carbon dioxide fluid further includes a co-solvent, such as methanol, surfactants, chelating agents, and combinations thereof. Cleaning of the substrate structure with a supercritical fluid and/or dense fluid may be accomplished without the need for a wet clean. Cleaning or drying of the substrate structure with a supercritical fluid and/or dense fluid may be accomplished without the need for prior art vacuum bakes. A substrate having at least one feature with high aspect ratio apertures can be advantageously cleaning and/or dried with a supercritical fluid and/or a dense fluid. High aspect ratio apertures also act like a sponge taking up contaminants, non-reactive precursors, liquids very easily and are difficult to clean and dry out.

In one embodiment, supercritical fluid and/or dense fluid may be used to clean a substrate structure after dry stripping. For example, supercritical fluid and/or dense fluid may be used to remove or clean photoresist residue 312 from the porous low-k material layer 306 of substrate structure 302 shown in FIG. 3E. In one embodiment, the supercritical fluid and/or dense fluid further includes a chelating agent to help remove or clean conductive material residue 314. In one aspect, cleaning of residue from a substrate structure with a supercritical fluid and/or dense fluid may be accomplished without the need for a wet clean. As a consequence, using a supercritical fluid and/or dense fluid to clean a substrate structure avoids the associated problems of using a wet clean.

In one embodiment, a substrate may be processed by applying a supercritical fluid thereto. In another embodiment, a substrate may be processed by applying a dense fluid thereto without the substance reaching a supercritical state. In still another embodiment, a substrate may be processed by applying a substance thereto in which the substance is phase modulated between a supercritical fluid state and a dense fluid state. A dense fluid may have a high solvating and diffusivity properties similar to a supercritical fluid. In one aspect, an apparatus adapted to apply a supercritical fluid to a substrate provides a supercritical fluid with greater solvating strength and diffusivity over a dense fluid. In another aspect, an apparatus adapted to only apply a dense fluid to a substrate is less complex than an apparatus adapted to apply a supercritical fluid due to the relatively higher temperatures and pressures used to achieve a supercritical fluid state.

In one preferred embodiment, the supercritical fluid and/or dense fluid used is carbon dioxide or xenon, more preferably carbon dioxide is used. In one aspect, carbon dioxide may be used to advantage as a supercritical fluid and/or dense fluid due to carbon dioxide's relatively low critical pressure (Pc=1050 psi) and relatively low critical temperature (Tc=31° C.) in comparison to other substances. In addition, carbon dioxide possesses less environmental risks in comparison to other substances which exhibit supercritical fluid properties. In one embodiment, dense carbon dioxide fluid comprises carbon dioxide at a temperature at least about 18° C. and at a pressure at least about 500 psi, and preferably comprises carbon dioxide at a temperature at least about 25° C. and at a pressure at least about 800 psi. In another embodiment, the supercritical fluid and/or dense fluid used is a fluid with a critical pressure below 4,500 psi, preferably below 2,000 psi, and/or a fluid with a critical temperature below 200° C., preferably below 120° C.

Supercritical fluids and/or dense fluids, such as carbon dioxide, may be used to advantage in processing a variety of materials used in semiconductor applications. Depending on the application, other optional components, such as co-solvents, surfactants, chelating agents, reactants, and combinations thereof, may be used in conjunction with the supercritical fluid and/or dense fluid. Examples of co-solvents include, but are not limited to, alcohols, halogenated solvents, esters, ethers, ketones, amines, amides, aromatics, aliphatic hydrocarbons, olefins, synthetic and natural hydrocarbons, organosilicones, alkyl pyrrolidones, paraffins, petroleum-based solvents, other suitable solvents, and mixtures thereof. The co-solvents may be miscible or immiscible with the supercritical fluid and/or dense fluid. Examples of chelating agents include, but are not limited to, chelating agent containing one or more amine or amide groups, such as ethylenediaminetetraacetic acid (EDTA), ethylenediaminedihyroxyphenylacetic acid (EDDHA), ethylenediamine, or methyl-formamide or other organic acids, such as iminodiacetic acid or oxalic acid. The term “surfactants” as used herein includes compounds that have one or more polar groups and one or more non-polar groups. It is believed that the surfactants help alter the interfacial characteristics of the supercritical fluid and/or dense fluid. Examples of surfactants include, but are not limited to, silicon-containing compounds, oxidizing agents, carbon-containing compounds, other reactants, and combinations thereof.

### Platforms

The applications of processing substrates as disclosed herein may be carried out in one or more single chamber systems, in one or more mainframe systems having a plurality of chambers, in separate processing systems, in an integrated processing system, or in combinations thereof.

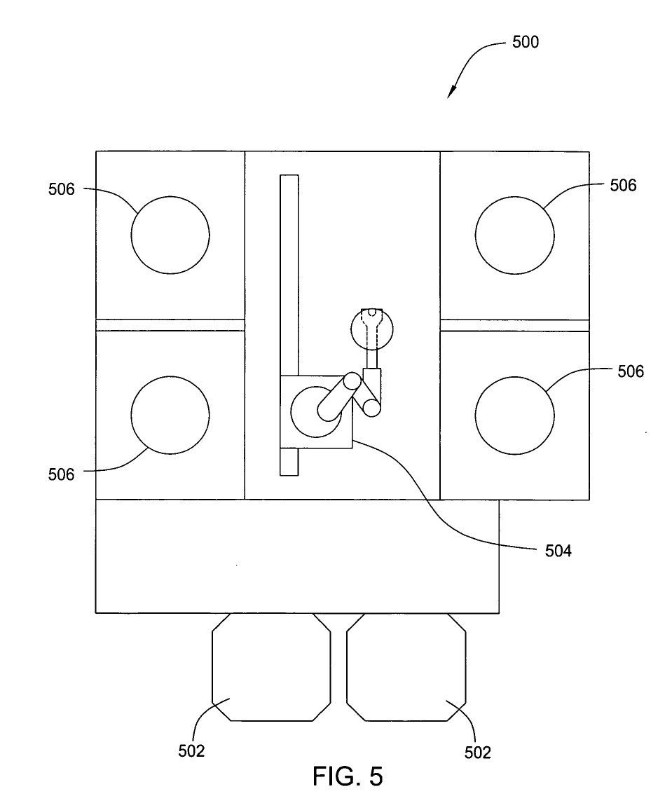

FIG. 5 is a schematic top view of one embodiment of an integrated system 900 capable of performing the processes disclosed herein. As shown in the figure, the integrated system 500 is a LINK™ platform, available from Applied Materials, Inc., located in Santa Clara, Calif. The system 500 generally includes one or more substrate cassettes 502, one or more transfer robots 504, and one or more processing chambers 506.

One example of the system 500 adapted to perform the method as described in FIG. 4 comprises at least one of the processing chamber 506 adapted to provide a wet clean, such as a TEMPEST™ chamber, available from Applied Materials, Inc, located in Santa Clara, Calif. The system 500 further comprises at least one of the processing chambers 506 adapted to provide a supercritical fluid and/or a dense fluid, such as processing chamber 100 of FIG. 1 or processing chamber 200 of FIG. 2. The system 500 further optionally further comprises at least one processing chamber 506 adapted to provide a dry strip, such as an AXIOM™ chamber, available from Applied Materials, Inc., located in Santa Clara, Calif.

One example of the system 500 adapted to perform the method as described in FIG. 5 comprises at least one processing chamber 506 adapted to provide a dry strip, such as an AXIOM™ chamber, available from Applied Materials, Inc., located in Santa Clara, Calif. The system 500 further comprises at least one of the chambers 506 adapted to provide a supercritical fluid and/or a dense fluid, such as processing chamber 100 of FIG. 1 or processing chamber 200 of FIG. 2.

One example of the system 500 adapted to perform methods of the invention may include at least one of the chambers 506 adapted to provide a supercritical fluid and/or a dense fluid, such as the processing chamber 100 of FIG. 1 or the processing chamber 200 of FIG. 2. The system 500 further includes at least one processing chamber 506 adapted to provide a dry etch, such as an eMAX™ chamber or a DPS™ chamber, available from Applied Materials, Inc., located in Santa Clara, Calif. In addition, the system 500 may include at least one processing chamber 506 adapted to deposit a low-k material, such as a Black Diamond™ CVD chamber, available from Applied Materials, Inc., located in Santa Clara, Calif.

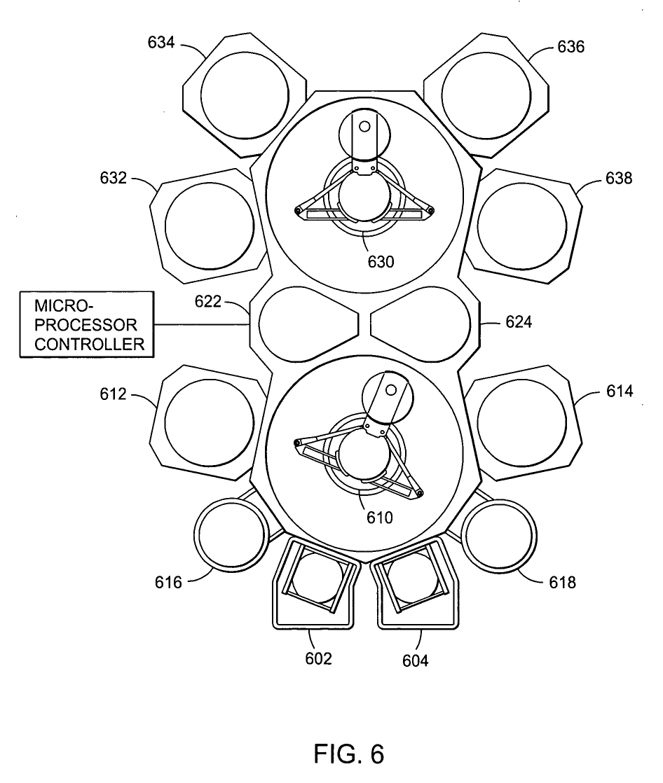

The processes as disclosed herein may be carried out in separate chambers or may be carried out in a multi-chamber processing system having a plurality of chambers. FIG. 6 is a schematic top-view diagram of another example of a multi-chamber processing system 600 which may be adapted to perform processes as disclosed herein. The apparatus is an ENDURA™ system and is commercially available from Applied Materials, Inc., of Santa Clara, Calif. A similar multi-chamber processing system is disclosed in U.S. Pat. No. 5,186,718, entitled “Stage Vacuum Wafer Processing System and Method,” (Tepman et al.), issued on Feb. 16, 1993, where is hereby incorporated by reference to the extent not inconsistent with the present disclosure. The particular embodiment of the system 600 is provided to illustrate the invention and should not be used to limit the scope of the invention.

The system 600 generally includes load lock chambers 602, 604 for the transfer of substrates into and out from the system 600. Typically, since the system 600 is under vacuum, the load lock chambers 602, 604 may “pump down” the substrates introduced into the system 600. A first robot 610 may transfer the substrates between the load lock chambers 602, 604, processing chambers 612, 614, transfer chambers 622, 624, and other chambers 616, 618. A second robot 630 may transfer the substrates between processing chambers 632, 634, 636, 638 and the transfer chambers 622, 624. Processing chambers 612, 614, 632, 634, 636, 638 may be removed from the system 600 if not necessary for the particular process to be performed by the system 600.

In one embodiment, the system 600 is configured so that at least one of the processing chambers is adapted to deposit a copper seed layer 410. For example, the processing chamber 634 for depositing a copper seed layer 410 may be the processing chamber 100 or the processing chamber 200. In addition, the processing chambers of the system 600 may include an annealing chamber, a pre-heating chamber, a cleaning chamber, a load lock chamber, a physical vapor deposition chamber, a chemical vapor deposition chamber, or an atomic layer deposition chamber. The system 600 may be further configured so that processing chamber 632 is adapted to deposit a barrier layer 204 in which the copper seed layer 410 is deposited over the barrier layer 204. For example, the processing chamber 632 for depositing the barrier layer 204 may be an atomic layer deposition chamber, a chemical vapor deposition chamber, or a physical vapor deposition chamber. In one aspect, deposition of a barrier layer 204 and a copper seed layer 410 may be performed in a multi-chamber processing system under vacuum to prevent air and other impurities from being incorporated into the layers and to maintain the seed structure over the barrier layer 204. Other embodiments of the system 600 are within the scope of the present invention. For example, the position of a particular processing chamber on the system may be altered. In another example, a single processing chamber may be adapted to deposit two different layers. The above particular embodiments of the systems 500, 600 to perform the process as disclosed herein is provided to illustrate the invention and should not be used to limit the scope of the invention unless otherwise set forth in the claims.

While the foregoing is directed to embodiments of the present invention, other and further embodiments of the invention may be devised without departing from the basic scope thereof, and the scope thereof is determined by the claims that follow.

What is claimed:

1. A method of processing a substrate inside a chamber, comprising:
delivering a fluid selected from the group consisting of a supercritical fluid, a dense fluid, and combinations thereof to the surface of the substrate having at least one feature thereon inside the chamber;
delivering one or more metal-containing precursor compounds to the surface of the substrate inside the chamber; and
depositing a metal material on the surface of the substrate.

2. The method of claim 1, wherein the fluid comprises carbon dioxide.

3. The method of claim 1, where the at least one feature is selected from the group consisting of trench, via, contact hole, and combinations thereof.

4. The method of claim 1, wherein the one or more metal-containing precursor compounds comprises a compound selected from the group consisting of Cu(hfac)2, Cu(tmod)2, Cu(tmhd)2, Cu(acac)2, Cuhfac(TMVS), Cu(DPM)2 their derivatives, and combinations thereof.

5. The method of claim 1, wherein the one or more metal-containing precursor compounds comprises a compound selected from the group consisting of bis(cyclopentadienyl) Ni, Ni(acac)2, Trimethylamine Alane(TEAA), Dimethylaluminum hydride(DMAH), Tri-isobutylAluminum(TIBA), pt(acac)2, Pd(acac)2, pd(C3H5)hfac, Bis(pentamethylcyclopentadienyl) manganese(II), Bis(cyclopentadienyl) manganese(II), Bis(ethylcyclopentadienyl) manganese(II), Bis(tetramethylcyclopentadienyl) manganese(II), Magnesium bis(2,2,6,6-tetramethyl-3,5-heptanedionate) hydrate, Bis(ethylcyclopentadienyl) magnesium, Bis(cyclopentadienyl) magnesium(II), Bis(pentamethylcyclopentadienyl) magnesium, ruthenium beta diketonates, cyclopentadienyl ruthenium, their derivatives, and combinations thereof.

6. The method of claim 1, the one or more metal-containing precursor compounds comprises at least two different metal-containing precursor compounds delivered sequentially to deposit a first metal material and a second metal material on the surface of the substrate.

7. The method of claim 1, wherein a co-solvent is applied to the substrate structure along with the fluid.

8. The method of claim 1, wherein a mixture of the fluid and the one or more metal-containing precursor compounds is formed prior to being delivered inside the chamber.

9. The method of claim 1, further comprising maintaining the pressure of the chamber near the supercritical pressure of the fluid.

10. The method of claim 1, further comprising maintaining the temperature of the chamber near the supercritical temperature of the fluid.

11. A method of processing a substrate inside a chamber, comprising:
delivering a fluid selected from the group consisting of a supercritical fluid, a dense fluid, and combinations thereof to the surface of the substrate having at least one feature thereon;
sequentially delivering at least two different metal-containing precursor compounds to the chamber; and
depositing a first metal material and a second metal material on the surface of the substrate.

12. The method of claim 11, wherein the fluid comprises carbon dioxide.

13. The method of claim 11, wherein one of the at least two different metal-containing precursor compounds is selected from the group consisting of Cu(hfac)2, Cu(tmod)2, Cu(tmhd)2, Cu(acac)2, Cuhfac(TMVS), Cu(DPM)2, their derivatives, and combinations thereof.

14. The method of claim 11, wherein one of the at least two different metal-containing precursor compounds is selected from the group consisting of bis(cyclopentadienyl) Ni, Ni(acac)2, Trimethylamine Alane(TEAA), Dimethylaluminum hydride(DMAH), Tri-isobutylAluminum(TIBA), pt(acac)2, Pd(acac)2, pd(C3H5)hfac, Bis(pentamethylcyclopentadienyl) manganese(II), Bis(cyclopentadienyl) manganese(II), Bis(ethylcyclopentadienyl) manganese(II), Bis(tetramethylcyclopentadienyl) manganese(II), Magnesium bis(2,2,6,6-tetramethyl-3,5-heptanedionate) hydrate, Bis(ethylcyclopentadienyl) magnesium, Bis(cyclopentadienyl) magnesium(II), Bis(pentamethylcyclopentadienyl) magnesium, ruthenium beta diketonates, cyclopentadienyl ruthenium, their derivatives, and combinations thereof.

15. The method of claim 11, wherein a mixture of the fluid and the at least two different metal-containing precursor compounds is formed prior to being delivered inside the chamber.

16. An apparatus for processing a substrate, comprising:
a chamber comprising walls defining an enclosure, the chamber adapted to be pressurized to a pressure of at least about 1000 psi;
a substrate support disposed within the enclosure, the substrate support having a substrate receiving surface;
a fluid delivery device adapted to deliver a fluid selected from the group consisting of a supercritical fluid, a dense fluid, and combinations thereof to the substrate receiving surface;
a fluid supply adapted to deliver one or more metal-containing precursor compounds;
a fluid line coupled between the fluid delivery device and the fluid supply; and
one or more heating elements.

17. The apparatus of claim 16, wherein the one or more heating elements are disposed at the fluid line.

18. The apparatus of claim 16, wherein the one or more heating elements are disposed at the walls of the chamber.

19. The apparatus of claim 16, further comprising one or more transducers disposed within the enclosure.

20. A system, comprising:
one or more first chambers adapted to deliver one or more metal-containing precursor compounds and a fluid selected from the group consisting of a supercritical fluid, a dense fluid, and combinations thereof to the substrate receiving surface and deposit a metal material on the surface of a substrate using a supercritical fluid and/or a dense fluid process;
one or more second chambers selected from the group consisting of a vapor deposition chamber, an annealing chamber, a wet clean chamber; a dry stripping chamber, a dry etch chamber, and a porous low-k deposition chamber; and combinations thereof; and
one or more transfer robots adapted to transfer substrates between the first chambers and second chambers.
